(19) United States
(12) Patent Application Publication
(10) Pub. No.: US 2010/0264492 A1
(43) Pub. Date: Oct. 21, 2010

(54) Semiconductor on Insulator Semiconductor Device and Method of Manufacture

(76) Inventors: Radu Surdeanu, Roosbeek (BE); Gerben Doornbos, Kessel-Lo (BE); Youri Ponomarev, Leuven (BE); Josine Loo, Heverlee (BE)

Correspondence Address: NXP, B.V.;NXP INTELLECTUAL PROPERTY & LICENSING, M/S41-SJ, 1109 MCKAY DRIVE, SAN JOSE, CA, 95131, US

(21) Appl. No.: 11/629,419

(22) PCT Filed: Jun. 6, 2006
(86) PCT No.: PCT/IB05/51832

§ 371 Date: Jul. 9, 2010

(30) Foreign Application Priority Data
Jun. 12, 2004 (GB) 0413133.0

(51) Int. Cl. H01L 29/786; H01L 21/86

(52) U.S. Cl. 257/348; 438/157; 257/E29.273; 257/E21.704

(57) ABSTRACT

A semiconductor on insulator semiconductor device has metal or silicide source and drain contact regions (38, 40), activated source and drain regions (30, 32) and a body region (34). The structure may be a double gated SOI structure or a fully depleted (FD) SOI structure. A sharp intergace and low resistance are achieved with a process that uses spacers (28) and which fully replaces the full thickness of a semiconductor layer with the contact regions.

The invention relates to a semiconductor on insulator (SOI) type semiconductor device, for example a double gated SOI device or a fully depleted semiconductor on insulator device (FD-SOI).

SOI technology has a number of advantages in specialized applications as has been realized for some time. More recently, it has been realized that SOI technology may also offer solutions to problems faced in more general applications of insulated gate transistors and in particular in scaling devices to achieve lower sizes.

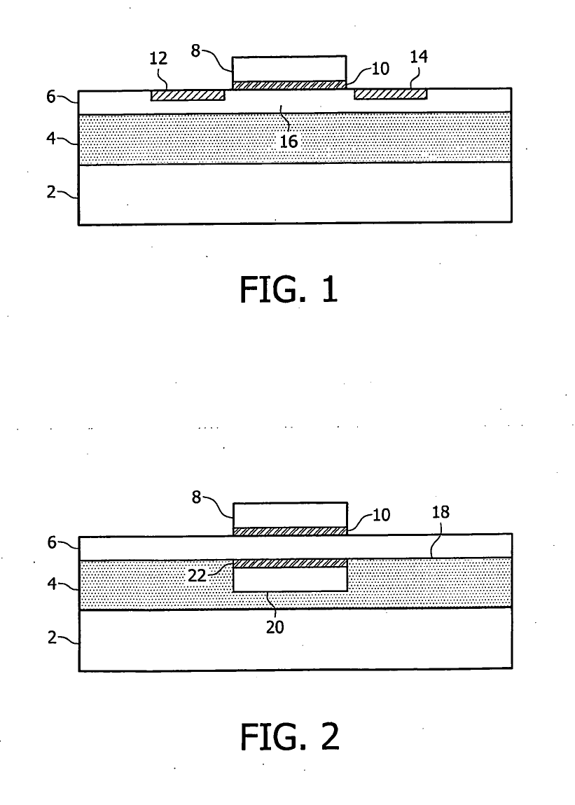

In the SOI device illustrated in FIG. 1, a layer of semiconductor 6 is provided over insulator 4 on a substrate 2, normally of silicon. A gate 8 is provided over the thin semiconductor layer insulated from it by gate insulator 10, and implanted source 12 and drain 14 electrodes provide the contacts. The semiconductor 16 between source and drain 12, 14 acts as a body. Conduction through the body between source and drain 12, 14 is controlled by the gate 8.

A particularly beneficial form of SOI technology is known as fully depleted SOI (FD-SOI). In this approach, the semiconductor layer 6 is very thin so that it is fully depleted. Electron transport between source and drain occurs only in the thin channel adjacent to the gate. FD-SOI has improved electrical characteristics, allowing optimization for high temperature, low voltage and low power applications.

A major challenge for FD-SOI is the manufacturing technology which is difficult. There is a need for improved processes to manufacture such devices.

A development of SOI technology is the double gated SOI structure (DG-SOI) in which a further insulated gate is provided below the semiconductor layer 6.

Conventionally, the manufacture of FD-SOI and DG-SOI devices use conventional complementary metal oxide semiconductor (CMOS) processing steps. The source, body and drain are defined using ion implantation and activation annealing. Unfortunately, in thin SOI devices such as FD-SOI and DG-SOI, the resulting sheet resistance and contact resistance are rather high. As a consequence, the series resistance of the transistor is high leading to sub-optimal performance of the transistor.

There is thus a need for a new transistor structure with a reduced series resistance and a method of making it.

According to the invention there is provided a transistor as set out in claim 1.

The semiconductor is preferably silicon.

The use of metallic contact regions together with activated source and drain regions instead of the conventional silicided doped silicon layers leads to a dramatic reduction in series resistance, one of the major problems for thin-body semiconductor devices.

The transistor may further include lower insulated gate below the channel region below the first planar surface, i.e. the transistor may be a double gated structure.

The doping in the activated regions may be at least 10¹⁹ cm⁻³, preferably at least 10²⁰ cm⁻³ and in particularly preferred embodiments at least 3×10²⁰ cm⁻³. By providing such highly doped regions, the effect of the Schottky barrier on current flow between the metallic contact regions and the activated semiconductor regions is minimized.

Preferably, an abrupt junction is formed between activated regions and the channel for best performance.

The source and drain contact regions may be of metal.

The invention also relates to method of manufacturing such transistors. Accordingly, in an aspect, the invention relates to a method of making a transistor, comprising:

providing a semiconductor on insulator substrate having a semiconductor layer above insulator;

defining an upper insulated gate above the semiconductor layer;

implanting source and drain regions in the semiconductor layer on either side of the gate leaving a body region between the source and drain regions under the upper insulated gate;

forming insulating spacers on the sides of the upper insulated gate;

implanting an amorphizing implant into the source and drain regions to render the whole of the semiconductor layer amorphous except where protected by the gate or the spacers;

removing the amorphous part of the semiconductor layer using a selective etch; and

depositing metallic contacts onto the source and drain regions.

The spacers may preferably have a thickness of 5 nm or less.

This method delivers a transistor with deposited metal source and drain contact regions, which may have a low resistance, together with highly doped activated source and drain regions in a small region defined by the spacers that gives a good contact between the source and drain contact regions and the channel through the body.

The method is highly integrateable in a CMOS process, and can be used for both FD-SOI and DG-SOI devices.

In another aspect, there is provided a method of making a transistor, comprising:

providing a semiconductor on insulator substrate having a semiconductor layer above insulator;

defining an upper insulated gate above the semiconductor layer;

implanting an amorphizing implant and dopant into the source and drain regions to render the whole of the semiconductor layer amorphous except where protected by the gate leaving a single crystalline body region between the source and drain regions under the upper insulated gate;

annealing the structure to regrow part of the doped amorphous regions starting from the single crystalline body region;

forming metallic contacts from the source and drain regions.

The activated regions have an abrupt junction with the channel which can significantly reduce leakage in the off-state of the semiconductor device.

The process is a low temperature process and accordingly integrateable into advanced CMOS flows.

The step of forming metallic contacts from the source and drain regions may include removing the amorphous part of the semiconductor layer using a selective etch; and depositing metallic contacts onto the source and drain regions. Such metallic contacts can have a much lower resistance than prior art approaches with the top layer of a silicon silicided.

The step of forming metallic contacts from the source and drain regions may alternatively include siliciding the source and drain regions to silicide the full thickness of these region.

The complete replacement of the thin-body silicon or other semiconductor with silicide reduces series resistance. Also, the siliciding process pushes dopants in the source and drain contact regions into the activated region, increasing the doping concentration there.

The step of annealing the structure to regrow part of the doped amorphous regions starting from the single crystalline body region may be carried out at a temperature from 500° C. to 750° C.

The annealing step may be carried out for a time to regrow from 3 nm to 10 nm of single crystal semiconductor.

Experiments suggest that the optimal regrowth is L_{gate}/6 plus from 1 to 3 nm, where L_{gate} is the length of the gate.

Implanting the amorphizing implant and the dopant may include the step of implanting an amorphizing implant into the semiconductor layer followed by the step of implanting a dopant into the semiconductor layer.

The step of implanting an amorphizing implant into the semiconductor layer may be carried out at a tilt of between 5° and 30°, preferably between 7° and 30° to get sufficient effect. Preferably, the tilt angle should be such that the overlap between amorphised semiconductor and the gate is about L_{gate}/6.

Alternatively, a single amorphizing and doping step may be used.

For a better understanding of the invention, embodiments will now be described, purely by way of example, with reference to the accompanying drawings in which:

FIG. 1 shows a prior art SOI structure;

FIG. 2 shows a double gated intermediate structure;

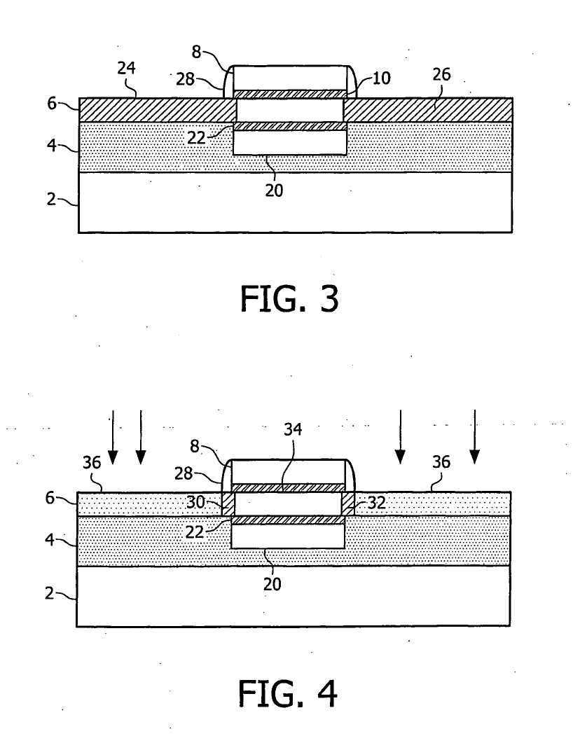

FIGS. 3 and 4 show intermediate steps in a first embodiment of a method according to the invention;

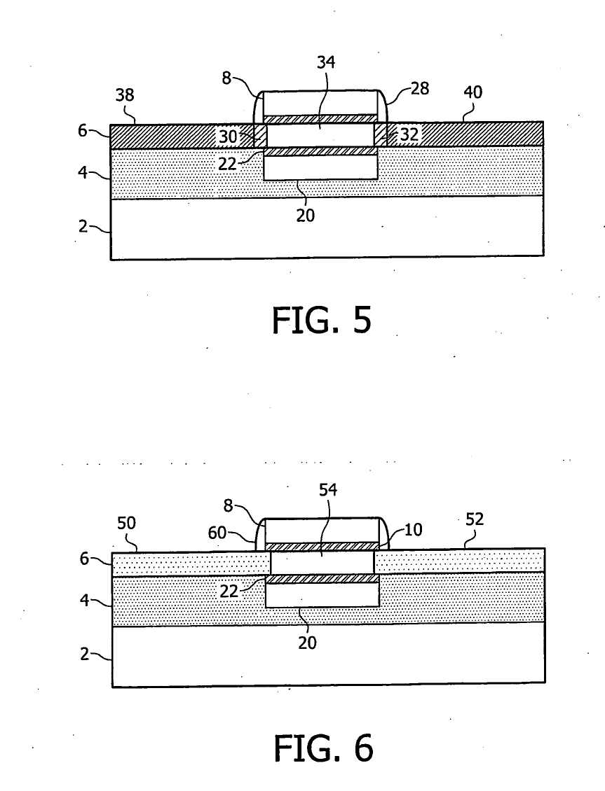

FIG. 5 shows a device according to the first embodiment of the invention;

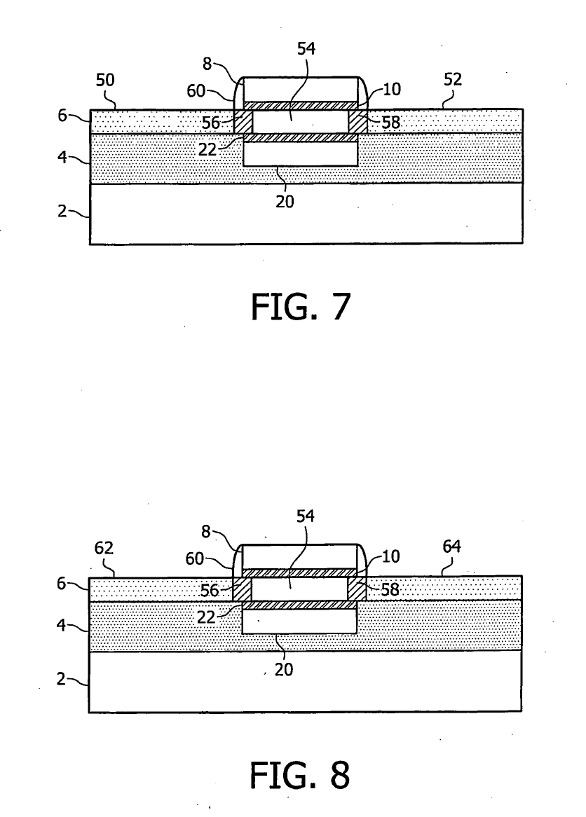

FIGS. 6 and 7 show intermediate steps in a second embodiment of the invention; and

FIG. 8 shows a device according to the second embodiment of the invention.

Note that the Figures are schematic and not to scale.

The method according to the invention starts by providing a structure with a thin layer of silicon 6 provided over insulator 4 on a substrate 2, also of silicon. An upper gate 8 is provided over the thin silicon layer insulated from it by gate insulator 10. A lower gate 20 is provided below the layer of silicon 6, likewise insulated from it by gate insulator 22, as illustrated in FIG. 2. Such structures are known to those skilled in the art and so their manufacture will not be described further.

A junction implant is then carried out to dope the source and drain regions 24,26. The doping should be heavy (at least 10¹⁹ cm⁻³) and for the full benefit of the invention the doping should be at least 10²⁰ cm⁻³. The doping can be either n- or p-type depending on whether an n-type or p-type transistor is being fabricated. The dopant may be B, In etc for a P-type transistor or P, As or Sb for an N-type transistor.

An anneal step follows, which can be a high ramp-rate spike, flash rapid thermal anneal or a sub-melt low-fluence laser anneal. The anneal step ensures the high level activation of the junction and a small diffusion under the gate.

Offset spacers 28 are now fabricated on the upper gate 8, using methods known in the art, such as depositing the material of the spacer on the whole surface and then etching the material away using an anisotropic etch to remove the material from the horizontal surface leaving the material just on the sidewalls of the gate to form the spacers 28. The spacers may be of oxide and/or nitride. The width of the spacers is preferably less than 5 nm. This results in the structure of FIG. 3.

An amorphizing implant is then performed amorphizing the full thickness of the silicon layer 6 except where protected by the spacers 28 and upper gate 8, leaving amorphous silicon regions 36 in the regions affected by the amorphizing. The implant can be of species such as Ge, As, Sb or In implanted at a dose and an energy to render the full thickness of silicon layer 6 amorphous. This step leaves activated source and drain regions 30, 32 under the spacers and a body region 34 between the two, as shown in FIG. 4.

Next, a selective etch is performed to remove the amorphous silicon regions 36, but not the crystalline regions 30,32,34 or the spacers. Such etches are known. For example, HF may be used if nitride spacers are used, or H₃PO₄ may be used if oxide spacers are used

Metal is then deposited selectively to form source and drain contact regions 38,40 to replace the removed amorphous silicon as shown in FIG. 5.

Processing then continues to finish the device as in conventional processes.

The method is easy to integrate in a CMOS flow and leads to a transistor with a highly reduced resistance. Although at first sight the Schottky barrier between the contact regions 38, 40 and the activated source and drain regions 30, 32, would seem to be highly disadvantageous, the activated regions can be highly doped and this reduces the effect of the barrier to reduce the overall resistance

A second embodiment of a method according to the invention starts with a device at the stage of FIG. 2.

Next, an initial amorphisation step is performed to create amorphous regions 50,52. The same species may be used as in the first embodiment, for example Ge, As, Sb or In, but in the second embodiment the implantation is done at a tilt. The tilt angle is selected so that the amorphous region overlaps the gate by about ⅙ of the gate length, leaving central region 54 between the amorphous regions 50, 52.

Next, dopant is implanted into the amorphous regions 50,52. The dopant may be B, In etc for a P-type transistor or P, As or Sb for an N-type transistor. This leads to the structure shown in FIG. 6.

In alternative embodiments a single implantation step can be used instead of the amorphisation and dopant implantation steps.

Next, a low temperature Solid Phase Epitaxy Regrowth (SPER) anneal step is performed, at a typical temperature of 500° C. to 750° C. Single crystal semiconductor now grows outwards from the central region 54, forming doped single crystal source and drain regions 56, 58. The regrowth time is tuned so that only a few nm of regrowth is obtained, typically 3-10 nm. Simulations suggest that the optimum regrowth depends on the gate length L_{g}, and should be of order L_{g}/6 plus from 1 to 3 nm.

After this step, a highly abrupt (<2 nm/decate), highly active (>3×10²⁰ cm⁻³) small junction is obtained between the doped single crystal regions 56,58 and the central channel region 54.

Thin spacers 60 are then fabricated, leaving the device as shown in FIG. 7.

In the embodiment shown, a silicidation process then takes place, by depositing metal and siliciding in separate steps or in a single step, so that the whole thickness of the remaining amorphous silicon is consumed. This results in silicide source and drain contact regions 62,64. The resulting structure is shown in FIG. 7, which differs from that shown in FIG. 5 in that the metal of FIG. 5 is replaced by the silicide in FIG. 8.

Due to the silicide process, dopants in the amorphous silicon will be pushed into the activated single crystal regions 56,58, further enhancing the doping in those regions improving device properties.

The structure can deliver great improvement of current drive due to a dramatic reduction of series resistance. The method delivers a highly abrupt junction between channel and metal thereby greatly improving the leakage current in the off-state by up to two orders of magnitude.

Alternatively, processing of the second embodiment can continue as in the first embodiment to replace the amorphous regions with metal, leading to a structure similar to that of FIG. 4.

Although the above embodiments have been described using silicon as the semiconductor, the invention is applicable to other semiconductors such as GaAs, InP, InSb, etc., with the appropriate choice of dopants, for example Zn and Mn.

The above embodiments are double gated structures. The invention is equally applicable to FD-SOI structures only with a single gate by simply omitting the lower gate 20 and gate insulator 22 from the structures.

From reading the present disclosure, other variations and modifications will be apparent to persons skilled in the art. Such variations and modifications may involve equivalent and other features which are already known in the design, manufacture and use of semiconductor devices and which may be used in addition to or instead of features described herein. Although claims have been formulated in this application to particular combinations of features, it should be understood that the scope of disclosure also includes any novel feature or any novel combination of features disclosed herein either explicitly or implicitly or any generalisation thereof, whether or not it mitigates any or all of the same technical problems as does the present invention. The applicants hereby give notice that new claims may be formulated to any such features and/or combinations of such features during the prosecution of the present application or of any further applications derived therefrom.

1. A transistor, comprising:
an insulated substrate defining a first planar surface of insulator;
source and drain contact regions on the first planar surface, the full thickness of the source and drain contact regions being of silicide or of metal the source and drain contact regions being laterally spaced apart;
a semiconductor region on the first planar surface between the source and drain contact regions, the semiconductor region comprising an activated source region adjacent to the source contact region, and activated drain region adjacent to the drain contact region (40,64), and a channel region between the activated source and drain regions; and
an upper insulated gate above the channel region.

2. A transistor according to claim 1 further comprising a lower insulated gate below the channel region below the first planar surface

3. A transistor according to claim 1 wherein the doping in the activated regions is at least 10¹⁹ cm⁻³.

4. A transistor according to claim 1 wherein the source and drain contact regions are of metal.

5. A method of making a transistor, comprising:
providing a semiconductor on insulator substrate having a semiconductor layer above insulator
defining an upper insulated gate above the semiconductor layer;
implanting source and drain regions in the semiconductor layer on either side of the gate leaving a body region between the source and drain regions under the upper insulated gate
forming insulating spacers on the sides of the upper insulated gate
implanting an amorphizing implant into the source and drain regions to define amorphous regions of the semiconductor layer the amorphous regions being the full thickness of the semiconductor layer except where protected by the gate or the spacers leaving activated source and drain regions around the body region protected by the gate or the spacers
removing the amorphous region of the semiconductor layer using a selective etch; and
depositing metallic source and drain contacts in contact with the activated source and drain regions respectively.

7. A method according to claim 6 wherein the spacers have a thickness of 5 nm or less.

8. A method of making a transistor, comprising:
providing a semiconductor on insulator substrate having a semiconductor layer above insulator
defining an upper insulated gate (8) above the semiconductor layer
implanting an amorphizing implant and dopant into the source and drain regions to render source and drain regions of the semiconductor layer amorphous except where the semiconductor layer is protected by the gate leaving a single crystalline body region between the source and drain regions under the upper insulated gate;
annealing the structure to regrow part of the doped amorphous regions starting from the single crystalline body region to form single crystal activated source and drain regions;
forming metallic contacts in contact with the activated source and drain regions

9. A method according to claim 8 wherein the step of forming metallic contacts includes removing the amorphous part of the semiconductor layer using a selective etch; and depositing metallic contacts onto the source and drain regions.

10. A method according to claim 8 wherein the step of forming metallic contacts includes siliciding the full thickness of the source and drain regions to form silicide source and drain contact regions.

11. A method according to claim 8 wherein the step of annealing the structure to regrow part of the doped amorphous regions starting from the single crystalline body region is carried out at a temperature from 500° C. to 750° C.

12. A method according to claim 8 wherein implanting the amorphizing implant and the dopant includes the step of implanting an amorphizing implant into the semiconductor layer followed by the step of implanting a dopant into the semiconductor layer

13. A method according to claim 12 wherein the step of implanting an amorphizing implant into the semiconductor layer is carried out at a tilt of between 5° and 30°.

14. A method according to claim 8 wherein the annealing step is carried out for a time to regrow a length from 3 nm to 10 nm of single crystal activated source region and of single crystal activated drain region
